(19) United States
(12) Patent Application Publication
(10) Pub. No.: US 2011/0188219 A1
(43) Pub. Date: Aug. 4, 2011

(54) CIRCUIT BOARD ASSEMBLY

(75) Inventor: JENG-DA WU, Tu-Cheng (TW)

(73) Assignee: HON HAI PRECISION INDUSTRY CO., LTD., Tu-Cheng (TW)

(21) Appl. No.: 12/753,299

(22) Filed: Apr. 2, 2010

(30) Foreign Application Priority Data
Feb. 1, 2010 (CN) 201020302040.9

(51) Int. Cl. H05K 1/18

(52) U.S. Cl. 361/783

(57) ABSTRACT

A circuit board assembly includes a circuit board having a first side and a second side opposite to the first side. A chip module is connected to the first side of the circuit board. The chip module includes a substrate and a chip disposed on the substrate. The first clamping member defines a recess and a contact portion around the recess. The chip is received in the recess, and the contact portion abuts the substrate. A second clamping member abuts the second side of the circuit board. A plurality of stress adjusting members extends through the second clamping member and engages the first clamping member.

### BACKGROUND

1. Technical Field

The present disclosure relates to circuit board assemblies, more particularly, to a circuit board assembly configured to minimize or prevent damage to a chip on a circuit board when the circuit board suffers impact.

2. Description of Related Art

A semiconductor chip is usually mounted on a printed circuit board by soldering spots of the semiconductor chip to the printed circuit board using a leaded solder material. The alloy resists damage easily, because of lead's resistance to shock. Due to environmental and health concerns, though, nonleaded solder is now commonly used. However, the non-leaded solder's low shock resistance, damage can easily occur, thereby affecting signal transmission between the semiconductor chip and the printed circuit board.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a circuit board assembly as disclosed.

FIG. 2 is an exploded, isometric view of a circuit board assembly similar to FIG. 1, but viewed from another aspect.

FIG. 3 is an assembled view of FIG. 1.

FIG. 4 is a cut view of the circuit board assembly mounted in a computer enclosure, along a direction IV-IV.

FIG. 5 is an enlarged view of portion V in FIG. 3.

FIG. 6 is a diagram of an acceleration curve used for simulating impact applied to the circuit board assembly.

FIG. 7 shows a curve illustrating points A and D of solder material disposed on a commonly used circuit board assembly.

FIG. 8 shows a curve illustrating points A and D of the circuit board assembly in FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

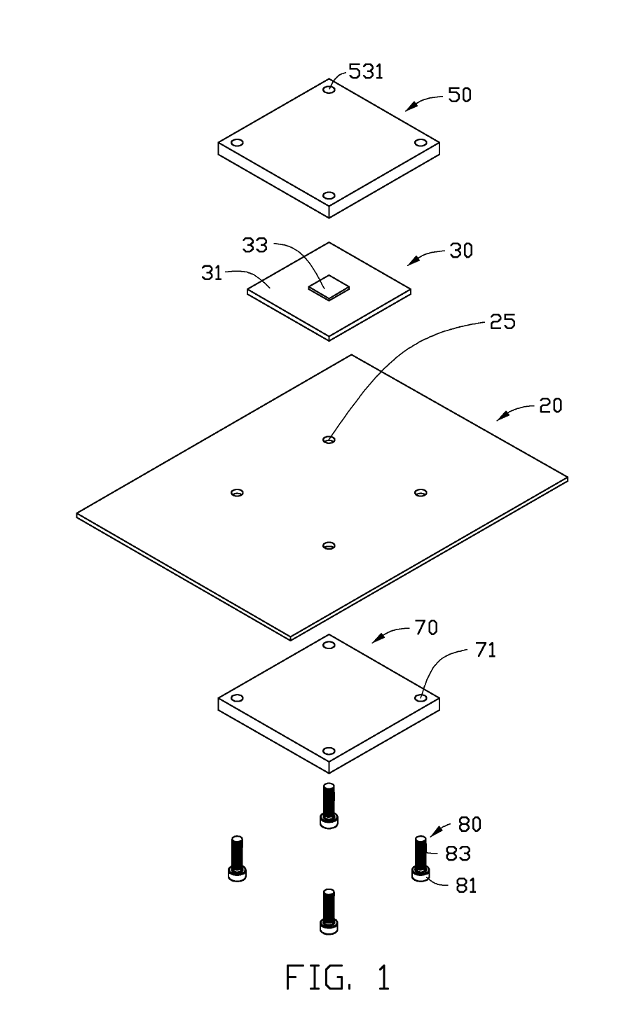

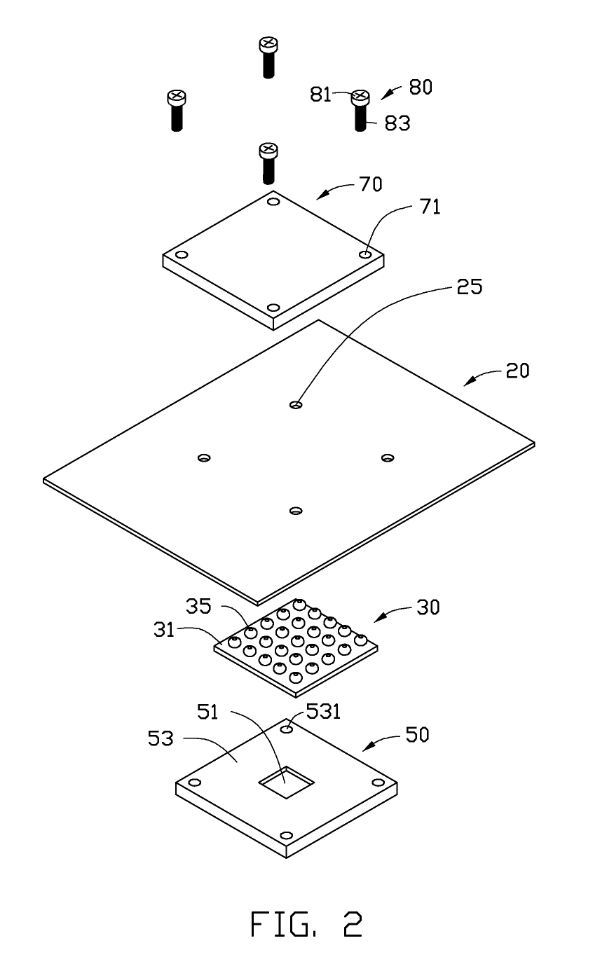

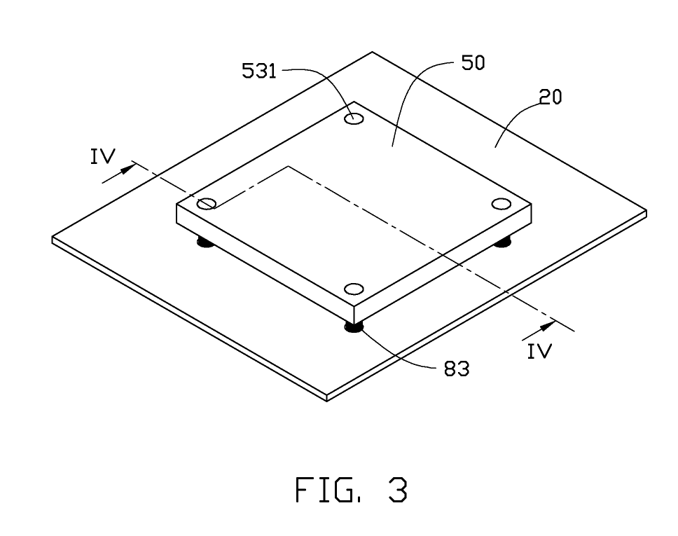

Referring to FIGS. 1 to 2, a circuit board assembly in accordance with the disclosure includes a circuit board 20 mounted in a computer enclosure 10, a chip module 30 disposed on the circuit board 20, a first clamping member 50, a second clamping member 70, and a plurality of stress adjusting members 80. The computer enclosure 10 includes a bottom surface 11 (shown in FIG. 3).

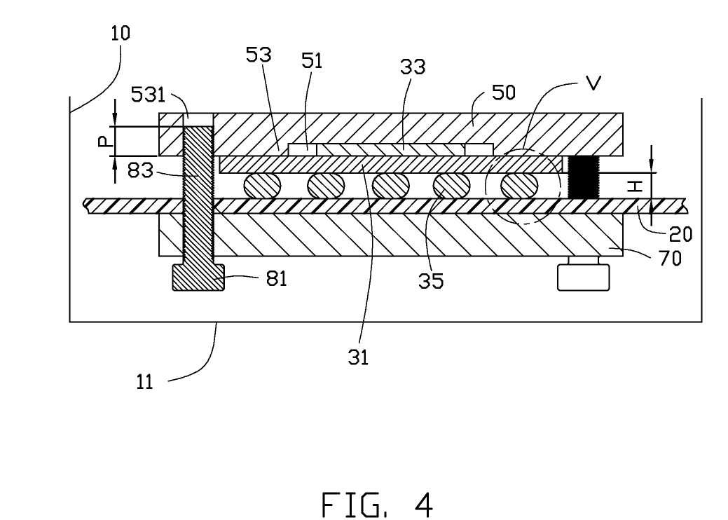

The chip module 30 includes a substrate 31 and a chip 33 disposed on the substrate 31. The substrate 31 is connected to the circuit board 20 via a plurality of solder balls 35 (shown in FIG. 4) connected to circuit board 20. In FIG. 2, the solder balls 35 are illustrated on the chip module 30, for ease of illustration. A plurality of through holes 25 is defined in the circuit board 20 around the chip module 30.

The first clamping member 50 defines a substantially rectangular recess 51 receiving the chip 33. A contact portion 53 is formed on the first clamping member 50 around the recess 51. A depth of the recess 51 is substantially equal to a height of the chip 33. Each corner of the contact portion 53 defines a threaded hole 531. In one embodiment, the first clamping member 50 is substantially rectangular.

The second clamping member 70 defines a plurality of mounting holes 71 corresponding to the threaded holes 531 of the first clamping member 50 and the through holes 25 of the circuit board 20. In one embodiment, the second clamping member 70 is substantially rectangular.

Each stress adjusting member 80 includes a head 81 and a threaded shaft 83.

Referring to FIGS. 3 and 4, in assembly, the chip module 30 is connected to a first side of the circuit board 20. The contact portion 53 of the first clamping member 50 abuts on the substrate 31 of the chip module 30 and extends out of the substrate 31. The threaded holes 531 are located in an extending area of the contact portion 53. The chip 33 is received in the recess 51 of the first clamping member 50. The second clamping member 70 abuts a second side of the circuit board 20. The threaded holes 531 in the first clamping member 50 and the mounting holes 71 in the second clamping member 70 align with the through holes 25 in the circuit board 20. The threaded shafts 83 of the plurality of stress adjusting members 80, extend through the mounting holes 71 and the through holes 25, insert in and engage with the threaded holes 531 in the first clamping member 50. Thus, the first clamping member 50 and the second clamping member 70 are secured to the circuit board 20. The circuit board 20 and the chip module 30 are clamped between the first clamping member 50 and the second clamping member 70. The circuit board 20 with the first clamping member 50 and the second clamping member 70 is secured to the bottom surface 11 of the computer enclosure 10. Distance between the circuit board 20 and the bottom surface 11 exceeds a thickness of the second clamping member 70.

When the computer enclosure 10 suffers an impact, tensile stress on the solder balls 35 between the circuit board 20 and the chip module 30 is reduced, since the circuit board 20 and the chip module 30 are clamped between the first clamping member 50 and the second clamping member 70, to place the tin balls 35 under compression. Thereby, the solder balls 35 are protected from being damaged.

The compressive stress applied to the solder balls 35 is determined by the stress adjusting members 80. The compressive stress applied to the solder balls 35 may be adjusted according to a ratio value of a length (P) of each threaded shaft 83 extending into the corresponding threaded holes 531 of the first clamping member 50 to a height (H) of each solder ball 35, or a distance between the substrate 31 and the circuit board 20. As ratio value P/H increases, stress applied to the solder balls 35 increases correspondingly. The stress adjusting members 80 may be operated to adjust the compressive stress applied on the solder balls 35, to counteract the tensile stress applied on the solder balls 35 during an impact.

At rest, the relationship between the ratio value P/H and the compressive stress applied to the solder balls 35 by different materials can be expressed as:

| P/H (%) | SnAgCu (Mpa) | Sn/Pb (Mpa) |
|---|---|---|
| 0.1 | 4.3 | 3.4 |
| 0.3 | 12.9 | 10.2 |
| 0.5 | 21.5 | 17 |
| 0.75 | 32.25 | 25.5 |
| 1 | 43 | 34 |
| 1.25 | 53.75 | 42.5 |
| 1.5 | 64.5 | 51 |
| 1.75 | 75.25 | 59.5 |
| 2 | 86 | 68 |
| 2.25 | 96.75 | 76.5 |
| 2.5 | 107.5 | 85 |
| 2.75 | 118.25 | 93.5 |
| 3 | 129 | 102 |

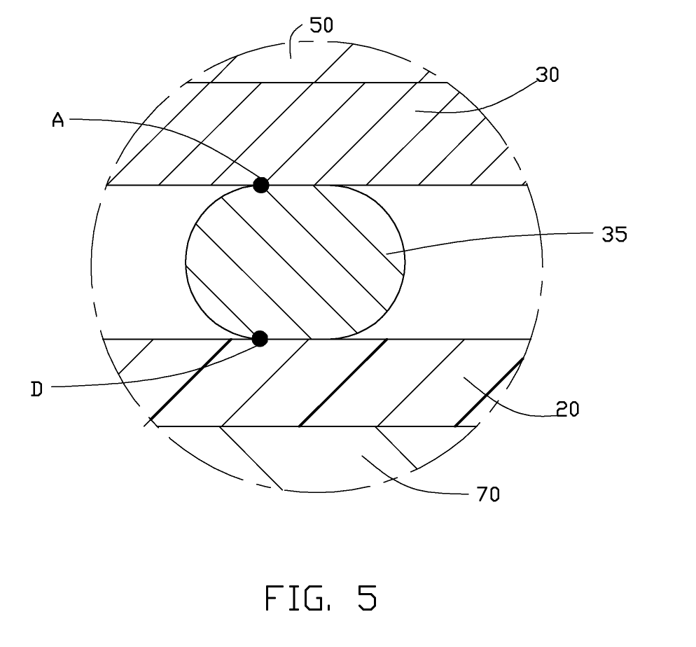

As shown in FIGS. 5 to 8, an application LS-DYNA simulates first principal stress applied to the solder balls 35 when the circuit board 20 suffers an impact. Generally, when the circuit board assembly suffers an impact, joints between the circuit board 20 and the solder balls 23 and between the chip 21 and the solder balls 23 suffer greater stress. Accordingly, during the simulation, only the first principal stresses, applied to a point A of one solder ball 23 at a joint between the circuit board 20 and the solder ball 23 and a point D at a joint between the chip 21 and the solder balls 23 are simulated. An acceleration curve (shown in FIG. 5) is used for simulating the impact applied on the circuit board 20. According to the simulation results, when the ratio P/H is greater than or equal to 0.5% and is less than or equal to 2.5%, the tensile stress applied on the points A and D can be effectively counteracted by the compressive stress applied on the solder balls 35 by the stress adjusting members 80. Thus, the solder balls 35 are protected from damage.

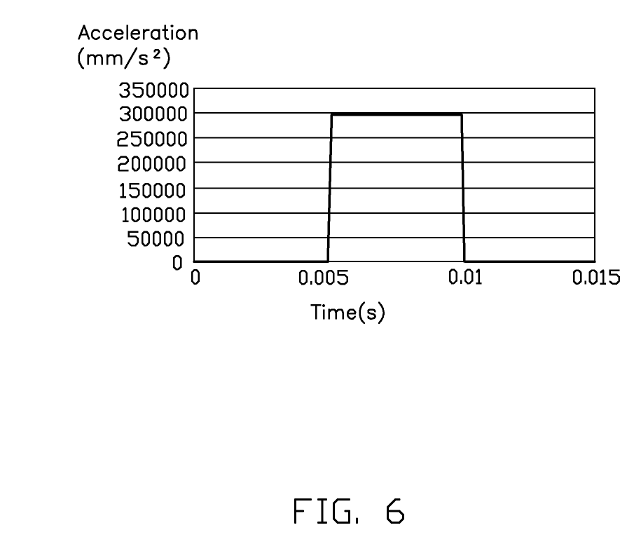

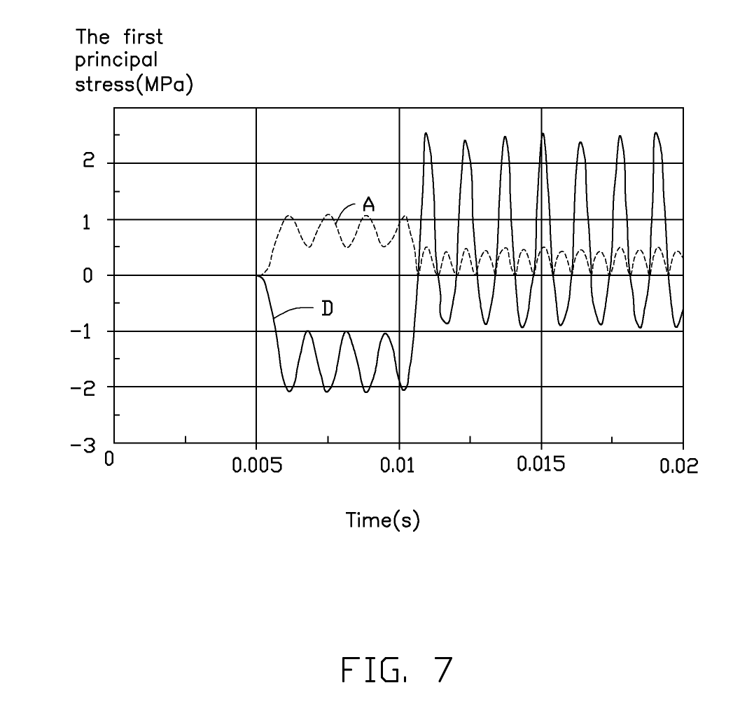

FIG. 7 shows the first principal stress distribution of the points A and D of a conventional circuit board assembly. The broken line shows the first principal stress distribution of the point A at a joint between the chip and a solder ball. The real line shows the first principal stress distribution of the point D at a joint between the solder ball and the circuit board. When the first principal stress value is positive, the solder balls suffer tensile stress. When the first principal stress value is negative, the solder balls suffer compressive stress. Generally, the solder balls are not damaged under greater compressive stress, but may be easily damaged under greater tensile stress. Referring to FIG. 6, the first principal stress values on the point A are all positive. Most of the stress values on the point D are positive and exceed 2 MPa. Thus, points A and D suffer great tensile stress, and are easily damaged.

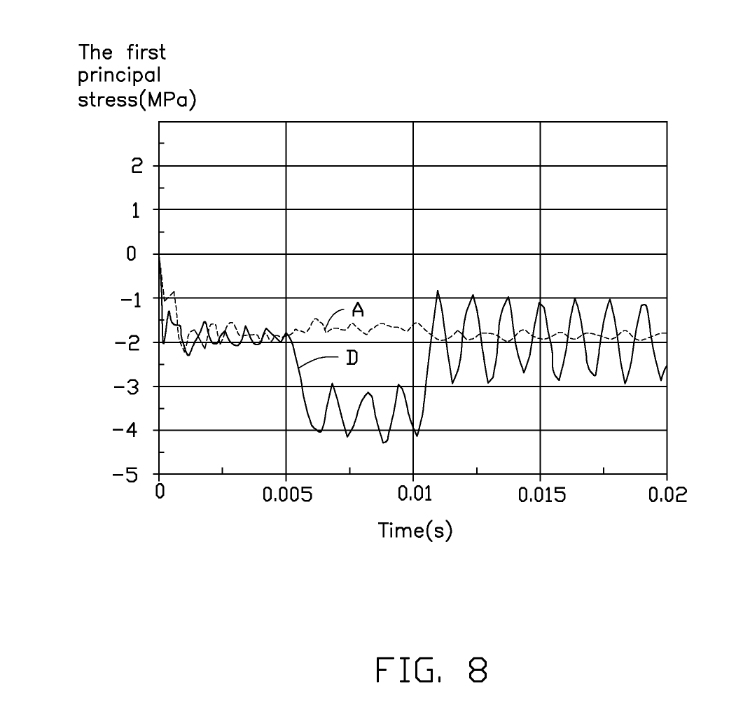

FIG. 8 shows the first principal stress distribution of the points A and D of the circuit board assembly when the ratio P/H value is 1%. The first principal stress values of the points A and D of the solder balls 23 are all negative. That is, when the circuit board assembly suffers impact, the points A and D of the solder balls 23 suffer only compressive stress, of a value small enough to be afforded and may not damage the solder balls. In actual use, the P/H value may be adjusted according to the expected external impact, to adjust the tensile stress applied on the solder balls 35, which are thereby protected from damage.

It is to be understood, however, that even though numerous characteristics and advantages of the embodiments have been set forth in the foregoing description, together with details of the structure and function of the present disclosure, the disclosure is illustrative only, and changes may be made in detail, especially in matters of, size, and arrangement of parts within the principles of the embodiments to the full extent indicated by the broad general meaning of the terms in which the appended claims are expressed.

What is claimed is:

1. A circuit board assembly, comprising:
a circuit board comprising a first side and a second side opposite to the first side;
a chip module connected to the first side of the circuit board, the chip module comprising a substrate and a chip disposed on the substrate;
a first clamping member defining a recess and a contact portion around the recess, the chip received in the recess, and the contact portion abuts the substrate;
a second clamping member abuts the second side of the circuit board; and
a plurality of stress adjusting members extending through the second clamping member and engaging with the first clamping member.

2. The circuit board assembly of claim 1, wherein a height of the chip is substantially equal to the depth of the recess of the first clamping member.

3. The circuit board assembly of claim 2, wherein the contact portion of the first clamping member extends out of the substrate of the chip module, and a plurality of threaded holes is defined in an extending area of the contact portion; a plurality of mounting holes is defined in the second clamping member and corresponds to the plurality of threaded holes; and a plurality of through holes is defined in the circuit board.

4. The circuit board assembly of claim 3, wherein each stress adjusting member includes a head and a threaded shaft, the head abuts the second clamping member, and the threaded shaft engages one of the plurality of threaded holes and extends through the one of the plurality of mounting holes and one of the plurality of though holes.

5. The circuit board assembly of claim 4, wherein the substrate of the chip module is connected to the circuit board via a plurality of solder balls.

6. The circuit board assembly of claim 5, wherein a ratio of a length of each of the threaded shafts received in one of the plurality of threaded holes of the first clamping member to a height of each solder ball is greater than or equal to 0.5% and is less than or equal to 2.5%.

7. The circuit board assembly of claim 5, wherein a ratio of a length of each of the threaded shafts received in one of the plurality of threaded holes of the first clamping member to a distance between the substrate and the circuit board is greater than or equal to 0.5% and less than or equal to 2.5%.

8. A circuit board assembly, comprising:
a circuit board comprising a first side and a second side opposite to the first side;
a chip module connected to the first side of the circuit board, the chip module comprising a substrate and a chip disposed on the substrate;
a first clamping member defining a recess and a contact portion around the recess, the chip is received in the recess, and the contact portion abuts the substrate;
a second clamping member abuts the second side of the circuit board; and
a plurality of stress adjusting members securing the second clamping member with the first clamping member to clamp the circuit board, the plurality of stress adjusting members engage the first clamping member and the second clamping member to adjust the stress applied on the chip module.

9. The circuit board assembly of claim 8, wherein a height of the chip is substantially equal to the depth of the recess of the first clamping member.

10. The circuit board assembly of claim 9, wherein the contact portion of the first clamping member extends out of the substrate of the chip module, and a plurality of threaded holes is defined in the extending area of the contact portion; a plurality of mounting holes is defined in the second clamping member and corresponds to the plurality of threaded holes; and a plurality of through holes is defined in the circuit board.

11. The circuit board assembly of claim 10, wherein each stress adjusting member includes a head and a threaded shaft, the head abuts the second clamping member, and the threaded shaft engages one of the plurality of threaded holes and extends through one of the plurality of mounting holes and one of the plurality of though holes.

12. The circuit board assembly of claim 11, wherein the substrate of the chip module is connected to the circuit board via a plurality of solder balls.

13. The circuit board assembly of claim 12, wherein a ratio of a length of each of the threaded shafts received in one of the plurality of threaded holes of the first clamping member to a height of each solder ball is greater than or equal to 0.5% and is less than or equal to 2.5%.

14. The circuit board assembly of claim 13, wherein a ratio of a length of each of the threaded shafts received in one of the plurality of threaded holes of the first clamping member to a distance between the substrate and the circuit board is greater than or equal to 0.5% and is less than or equal to 2.5%.
